(19) United States
(12) Patent Application Publication
(10) Pub. No.: US 2015/0034959 A1
(43) Pub. Date: Feb. 5, 2015

(54) PATTERNED SUBSTRATE AND LIGHT EMITTING DIODE STRUCTURE HAVING THE SAME

(71) Applicant: Lextar Electronics Corporation, Hsinchu (TW)

(72) Inventors: Yi-Ju CHEN, New Taipei City (TW); Der-Ling HSIA, New Taipei City (TW); Chih-Wei CHAO, Taipei City (TW); Cheng-Ta KUO, Hsinchu City (TW)

(73) Assignee: Lextar Electronics Corporation, Hsinchu (TW)

(21) Appl. No.: 14/246,885

(22) Filed: Apr. 7, 2014

(30) Foreign Application Priority Data
Jul. 31, 2013 (TW) 102127449

(51) Int. Cl. H01L 33/22; H01L 33/30

(52) U.S. Cl. CPC H01L 33/22; H01L 33/30
USPC 257/76; 428/141; 257/98

(57) ABSTRACT

A light emitting diode structure includes a patterned substrate, an N-type semiconductor layer, a light emitting layer, and a P-type semiconductor layer. Plural protruding portions are formed on a surface of the substrate. A horizontal projection of each of the protruding portions on the surface of the substrate has a projection width W1. An interval width W2 is formed between every two adjacent protruding portions. A vertical height h is formed between a peak of each of the protruding portions and the horizontal surface of the surface of the substrate. The value of {[(W1)/2+W2]/h} is substantially equal to tan 46°. The N-type semiconductor layer is located on the substrate and covers the protruding portions. The light emitting layer is located on the N-type semiconductor layer. The P-type semiconductor layer is located on the light emitting layer.

### RELATED APPLICATIONS

This application claims priority to Taiwan Application Serial Number 102127449, filed Jul. 31, 2013, which is herein incorporated by reference.

### BACKGROUND

1. Field of Invention

The present invention relates to a patterned substrate and a light emitting diode structure having the same.

2. Description of Related Art

A conventional light emitting diode structure may generally be composed of a sapphire substrate, N-type gallium nitride (N-GaN), a light emitting layer, and P-type gallium nitride (P-GaN). The surface of the sapphire substrate facing the light emitting layer can be patterned to form plural protruding portions and flat surfaces (also referred to as C surfaces). An included angle is formed between an incident light and a perpendicular line passing through the top end of the protruding portion.

When the light emitting layer emits light, concerning the refraction indexes of the sapphire substrate and the gallium nitride, only the incident lights with included angles from 0° to 23° above the light emitting layer may be successfully extracted. The incident lights with included angles from 0° to 46° can be refracted to the side surface of the sapphire substrate to be extracted. The incident lights with included angles greater than 46° are required to be changed in direction by the protruding portions of the sapphire substrate to be extracted.

Since the protruding portions of the sapphire substrate may change the directions of the incident lights, the light extraction efficiency of the entire light emitting diode structure is improved. With the higher proportion of the protruding portions of the sapphire substrate is the light extraction efficiency of the light emitting diode structure is getting higher. However, in manufacturing, when the proportion of the protruding portions reaches a certain high level and the proportion of the flat surfaces is low, the gallium nitride is difficultly grown on the sapphire substrate (i.e., epitaxial process). Therefore, pores are easily formed between the gallium nitride and the sapphire substrate. As a result, the internal quantum efficiency (IQE) of the light emitting diode structure is reduced, such that the luminous quality of the light emitting layer is reduced.

### SUMMARY

An aspect of the present invention is to provide a patterned substrate.

According to an embodiment of the present invention, a patterned substrate includes plural protruding portions which are formed on a surface of the substrate. A horizontal projection of each of the protruding portions on the surface of the substrate has a projection width W1. An interval width W2 is formed between every two adjacent protruding portions. A vertical height h is formed between a peak of each of the protruding portions and the horizontal surface of the surface of the substrate. The value of {[(W1)/2+W2]/h} is substantially in a range from tan 44° to tan 48°.

In an embodiment of the present invention, each of the protruding portions has a light-receiving surface for refracting or reflecting an incident light.

In an embodiment of the present invention, the light-receiving surface of each of the protruding portions is an oblique surface, and an obtuse angle is formed between the oblique surface and the surface of the substrate.

In an embodiment of the present invention, the light-receiving surface of each of the protruding portions is an arc surface.

In an embodiment of the present invention, the cross-sectional shapes of the protruding portions include triangle, semicircular, or combinations thereof.

In an embodiment of the present invention, the vertical height h is in a range from 1 μm to 1.5 μm.

In an embodiment of the present invention, [(W1)/2+W2] is in a range from 1.04 μm to 1.56 μm.

In an embodiment of the present invention, a refraction index of the N-type semiconductor layer is substantially equal to 2.5, and the refraction index of the substrate is substantially equal to 1.8.

In an embodiment of the present invention, the substrate is a sapphire substrate.

Another aspect of the present invention is to provide a light emitting diode structure.

According to an embodiment of the present invention, a light emitting diode structure includes a patterned substrate, an N-type semiconductor layer, a light emitting layer, and a P-type semiconductor layer. Plural protruding portions are formed on a surface of the substrate. A horizontal projection of each of the protruding portions on the surface of the substrate has a projection width W1. An interval width W2 is formed between every two adjacent protruding portions. A vertical height h is formed between a peak of each of the protruding portions and the horizontal surface of the surface of the substrate. The value of {[(W1)/2+W2]/h} is substantially in a range from tan 44° to tan 48°. The N-type semiconductor layer is located on the substrate and covers the protruding portions. The light emitting layer is located on the N-type semiconductor layer. The P-type semiconductor layer is located on the light emitting layer.

In an embodiment of the present invention, each of the protruding portions has a light-receiving surface for refracting or reflecting an incident light emitted by the light emitting layer.

In an embodiment of the present invention, the light-receiving surface of each of the protruding portions is an oblique surface, and an obtuse angle is formed between the oblique surface and the surface of the substrate.

In an embodiment of the present invention, the light-receiving surface of each of the protruding portions is an arc surface.

In an embodiment of the present invention, the cross-sectional shapes of the protruding portions include triangle, semicircular, or combinations thereof.

In an embodiment of the present invention, the vertical height h is in a range from 1 μm to 1.5 μm.

In an embodiment of the present invention, [(W1)/2+W2] is in a range from 1.04 μm to 1.56 μm.

In an embodiment of the present invention, the refraction index of the N-type semiconductor layer is substantially equal to 2.5, and the refraction index of the substrate is substantially equal to 1.8.

In an embodiment of the present invention, the substrate is a sapphire substrate.

In an embodiment of the present invention, the material of the P-type semiconductor layer is a nitride semiconductor including p-type dopant, and the material of the N-type semiconductor layer is a nitride semiconductor including N-type dopant.

In an embodiment of the present invention, the material of the P-type semiconductor layer is P-type gallium nitride, and the material of the N-type semiconductor layer is N-type gallium nitride.

In the aforementioned embodiments of the present invention, since the horizontal projection of each of the protruding portions on the surface of the substrate has the projection width W1, the interval width W2 is formed between every two adjacent protruding portions, the vertical height h is formed between the peak of each of the protruding portions and the horizontal surface of the surface of the substrate, and the value of {[(W1)/2+W2]/h} is substantially equal to tan 46°, when the vertical height h is a constant, [(W1)/2+W2] is also a constant (i.e., h·tan46°), and designers can adjust W1 and W2 in accordance with the condition.

When an included angle between an incident light emitted by the light emitting layer and a perpendicular line passing through the peak of the protruding portion is greater than 46°, the incident light can enter the substrate through the protruding portion by means of the design of the vertical height h, the projection width W1, and the interval width W2, and the suitable interval width W2 can be retained for growing the N-type semiconductor layer. As a result, the light emitting diode structure can have good luminous quality and light extraction efficiency.

### BRIEF DESCRIPTION OF THE DRAWINGS

The invention can be more fully understood by reading the following detailed description of the embodiment, with reference made to the accompanying drawings as follows:

FIG. 1 is a cross-sectional view of a light emitting diode structure according to an embodiment of the present invention;

FIG. 2 is a cross-sectional view of a light emitting diode structure according to an embodiment of the present invention;

FIG. 3 is a cross-sectional view of a light emitting diode structure according to an embodiment of the present invention;

FIG. 4 is a cross-sectional view of a light emitting diode structure according to an embodiment of the present invention;

FIG. 5 is a cross-sectional view of a light emitting diode structure according to an embodiment of the present invention; and

FIG. 6 is a cross-sectional view of a light emitting diode structure according to an embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

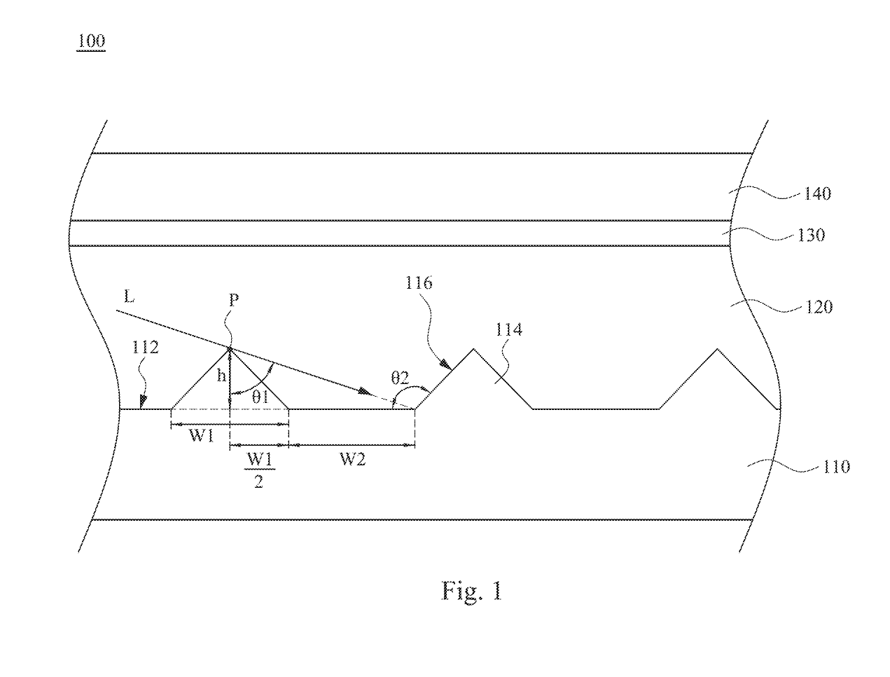

FIG. 1 is a cross-sectional view of a light emitting diode structure 100 according to an embodiment of the present invention. As shown in FIG. 1, the light emitting diode structure 100 includes a patterned substrate 110, an N-type semiconductor layer 120, a light emitting layer 130, and a P-type semiconductor layer 140. Plural protruding portions 114 are formed on a surface 112 of the substrate 110, and each of the protruding portions 114 has a light-receiving surface 116. A horizontal projection of each of the protruding portions 114 on the surface 112 has a projection width W1. An interval width W2 is formed between every two adjacent protruding portions 114. A vertical height h is formed between a peak P of each of the protruding portions 114 and the horizontal surface of the surface 112. Moreover, the value of {[(W1)/2+W2]/h} is substantially equal to tan 46°. In the following description, “substantially” is used to refer to the fact that there may be differences as a result of manufacturing errors. For example, {[(W1)/2+W2]/h} may be in a range from tan 44° to tan 48°, the vertical height h may be in a range from 1 μm to 1.5 μm, and [(W1)/2+W2] may be in a range from 1.04 μm to 1.56 μm. In this embodiment, the substrate 110 may be a sapphire substrate, and the protruding portions 114 may be made by photolithography and etching processes.

Furthermore, the N-type semiconductor layer 120 is located on the substrate 110 and covers the protruding portions 114. The light emitting layer 130 is located on the N-type semiconductor layer 120. The P-type semiconductor layer 140 is located on the light emitting layer 130. The material of the P-type semiconductor layer 140 is a nitride semiconductor including p-type dopant, such as P-type gallium nitride (P-GaN), and the material of the N-type semiconductor layer 120 is a nitride semiconductor including N-type dopant, such as N-type gallium nitride (N-GaN). In this embodiment, the refraction index of the N-type semiconductor layer 120 is substantially equal to 2.5, and the refraction index of the substrate 110 is substantially equal to 1.8.

Since {[(W1)/2+W2]/h} is substantially equal to tan 46°. when the vertical height h is a constant, [(W1)/2+W2] is also a constant (i.e., h·tan46°). As long as the value of [(W1)/2+W2] is (h·tan46°), designers can adjust the magnitude of the projection width W1 and the interval width W2. As a result, when an included angle θ1 between an incident light L emitted by the light emitting layer 130 and a perpendicular line passing through the peak P of the protruding portion 114 is greater than 46°, the incident light L will arrive at the light-receiving surface 116 of the protruding portion 114 by means of the design of the vertical height h, the projection width W1, and the interval width W2, such that the incident light L can be refracted or reflected by the protruding portion 114.

In addition, the light emitting diode structure 100 retains the suitable interval width W2 for growing the N-type semiconductor layer 120 (i.e., epitaxial process), such that pores can be prevented to form between the N-type semiconductor layer 120 and the substrate 110. As a result, the internal quantum efficiency (IQE) of the light emitting diode structure 100 will be improved and the light emitting diode structure 100 will have good luminous quality.

When the included angle θ1 between the incident light L emitted by the light emitting layer 130 and the perpendicular line passing through the peak P of the protruding portion 114 is in a range from 0° to 23°, the incident light L can be extracted from the above of the light emitting layer 130. When the included angle θ1 between the incident light L emitted by the light emitting layer 130 and the perpendicular line passing through the peak P of the protruding portion 114 is in a range from 0° to 46°, the incident light L enters the substrate 110 by refraction, such that the incident light L can be refracted from the side surface of the substrate 110. When the included angle θ1 between the incident light L emitted by the light emitting layer 130 and the perpendicular line passing through the peak P of the protruding portion 114 is greater than 46°, the direction of the incident light L can be changed by the protruding portion 114, such that the incident light L can enter the substrate 110 by reflection or refraction, and the incident light L can be extracted from the side surface of the substrate 110. Since the substrate 110 having the protruding portion 114 can increase the probability of the incident light L entering the substrate 110, the light extraction efficiency of the entire light emitting diode structure 100 can be improved.

In this embodiment, the light-receiving surface 116 of the protruding portion 114 may be an oblique surface, and an obtuse angle θ2 is formed between the oblique surface and the surface 112 of the substrate 110. The cross-sectional shape of the protruding portion 114 may be triangle. However, the types of the light-receiving surface 116 and the protruding portion 114 are not limited by the aforesaid types.

It is to be noted that the connection relationships and materials of the elements described above will not be repeated in the following description, and only aspects related to other types of the protruding portion 114 will be described.

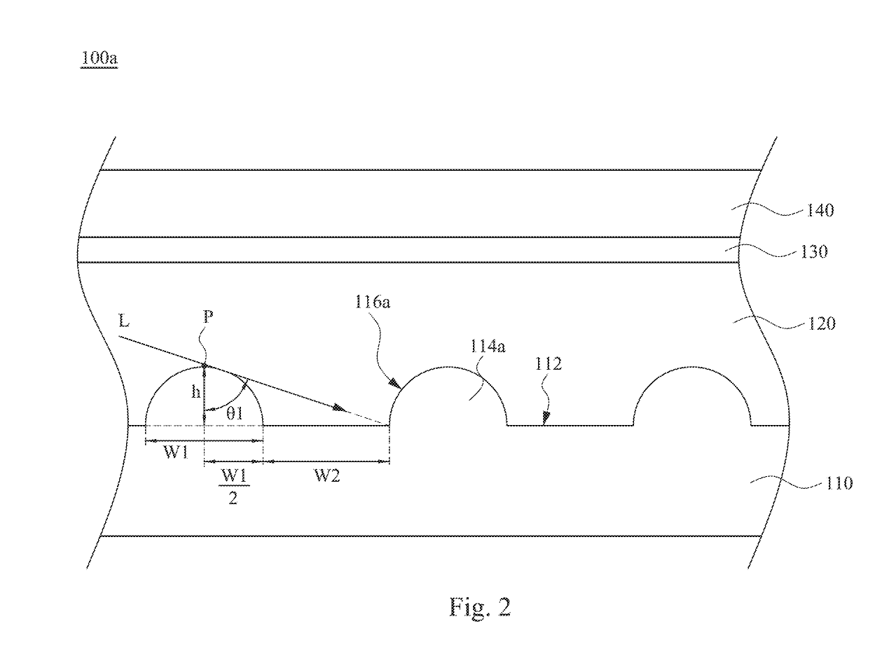

FIG. 2 is a cross-sectional view of a light emitting diode structure 100a according to an embodiment of the present invention. As shown in FIG. 2, the light emitting diode structure 100a includes the patterned substrate 110, the N-type semiconductor layer 120, the light emitting layer 130, and the P-type semiconductor layer 140, and the value of {[(W1)/2+W2]/h} is substantially equal to tan 46°. The differences between this embodiment and the embodiment shown in FIG. 1 are that the cross-sectional shape of the protruding portion 114a is semicircular, and the light-receiving surface 116a of the protruding portion 114a is an arc surface.

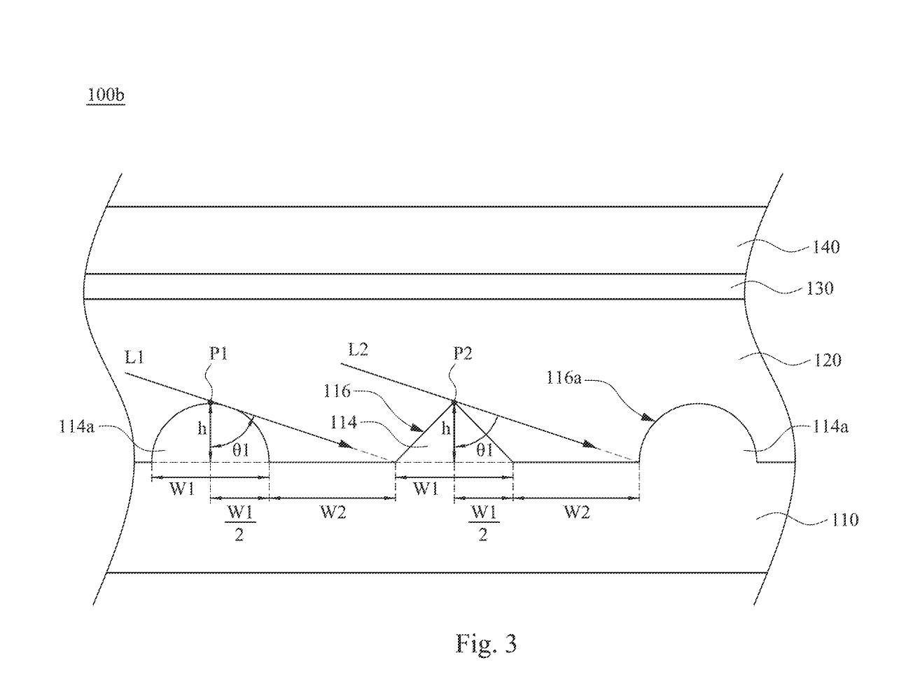

FIG. 3 is a cross-sectional view of a light emitting diode structure 100b according to an embodiment of the present invention. As shown in FIG. 3, the light emitting diode structure 100b includes the patterned substrate 110, the N-type semiconductor layer 120, the light emitting layer 130, and the P-type semiconductor layer 140, and the value of {[(W1)/2+W2]/h} is substantially equal to tan 46°. The difference between this embodiment and the embodiments shown in FIG. 1 and FIG. 2 is that the substrate 110 has the protruding portions 114 and 114a. The cross-sectional shape of the protruding portion 114 is triangle, and the light-receiving surface 116 of the protruding portion 114 is an oblique surface. The cross-sectional shape of the protruding portion 114a is semicircular, and the light-receiving surface 116a of the protruding portion 114a is an arc surface.

When the included angle θ1 between the incident light L emitted by the light emitting layer 130 and the perpendicular line passing through the peak P1 of the protruding portion 114a is greater than 46°, an incident light L1 can enter the substrate 110 through the light-receiving surface 116 of the protruding portion 114, such that the incident light L1 can be refracted or reflected by the protruding portion 114. Moreover, when the included angle θ1 between the incident light L2 emitted by the light emitting layer 130 and the perpendicular line passing through the peak P2 of the protruding portion 114 is greater than 46°, an incident light L2 can enter the substrate 110 through the light-receiving surface 116a of the protruding portion 114a, such that the incident light L2 can be refracted or reflected by the protruding portion 114a.

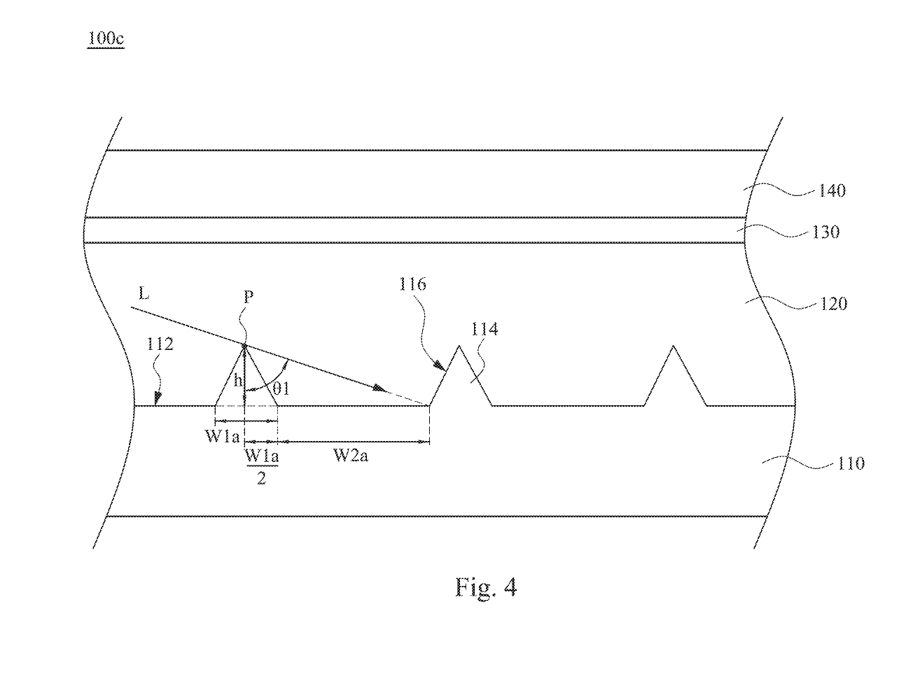

FIG. 4 is a cross-sectional view of a light emitting diode structure 100c according to an embodiment of the present invention. As shown in FIG. 4, the light emitting diode structure 100c includes the patterned substrate 110, the N-type semiconductor layer 120, the light emitting layer 130, and the P-type semiconductor layer 140, and the value of {[(W1a)/2+W2a]/h} is substantially equal to tan 46°. The differences between this embodiment and the embodiment shown in FIG. 1 are that the projection width W1a is smaller than the projection width W1 of FIG. 1, and the interval width W2a is greater than the interval width W2 of FIG. 1.

When the included angle θ1 between the incident light L emitted by the light emitting layer 130 and the perpendicular line passing through the peak P of the protruding portion 114 is greater than 46°, the incident light L can enter the substrate 110 through the light-receiving surface 116 of the protruding portion 114 by means of the design of the vertical height h, the projection width W1a, and the interval width W2a, such that the incident light L can be refracted or reflected by the protruding portion 114.

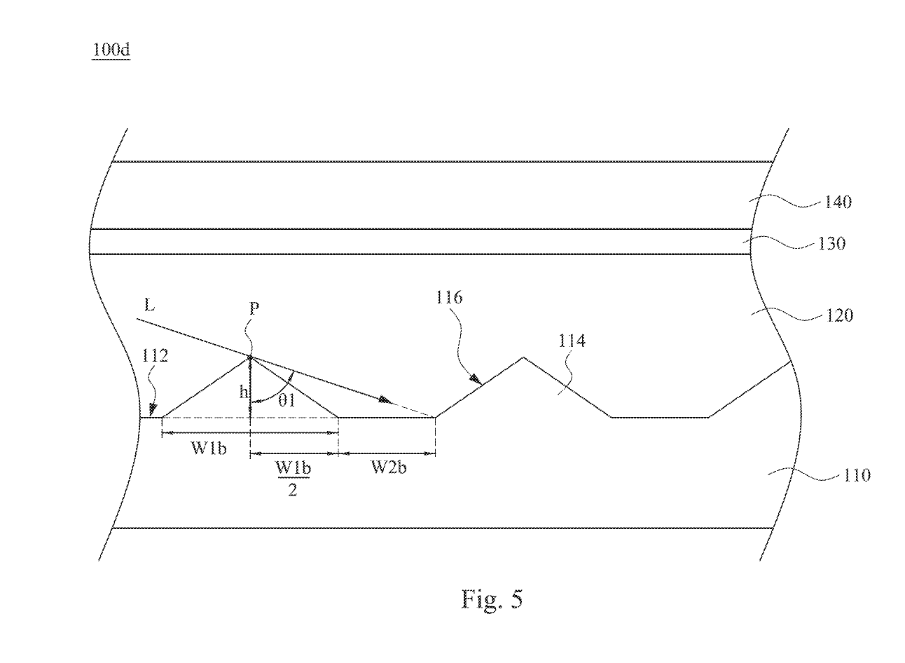

FIG. 5 is a cross-sectional view of a light emitting diode structure 100d according to an embodiment of the present invention. As shown in FIG. 5, the light emitting diode structure 100d includes the patterned substrate 110, the N-type semiconductor layer 120, the light emitting layer 130, and the P-type semiconductor layer 140, and the value of {[(W1b)/2+W2b]/h} is substantially equal to tan 46°. The differences between this embodiment and the embodiment shown in FIG. 1 are that the projection width W1b is greater than the projection width W1 of FIG. 1, and the interval width W2b is smaller than the interval width W2 of FIG. 1.

When the included angle θ1 between the incident light L emitted by the light emitting layer 130 and the perpendicular line passing through the peak P of the protruding portion 114 is greater than 46°, the incident light L can enter the substrate 110 through the light-receiving surface 116 of the protruding portion 114 by means of the design of the vertical height h, the projection width W1b, and the interval width W2b, such that the incident light L can be refracted or reflected by the protruding portion 114.

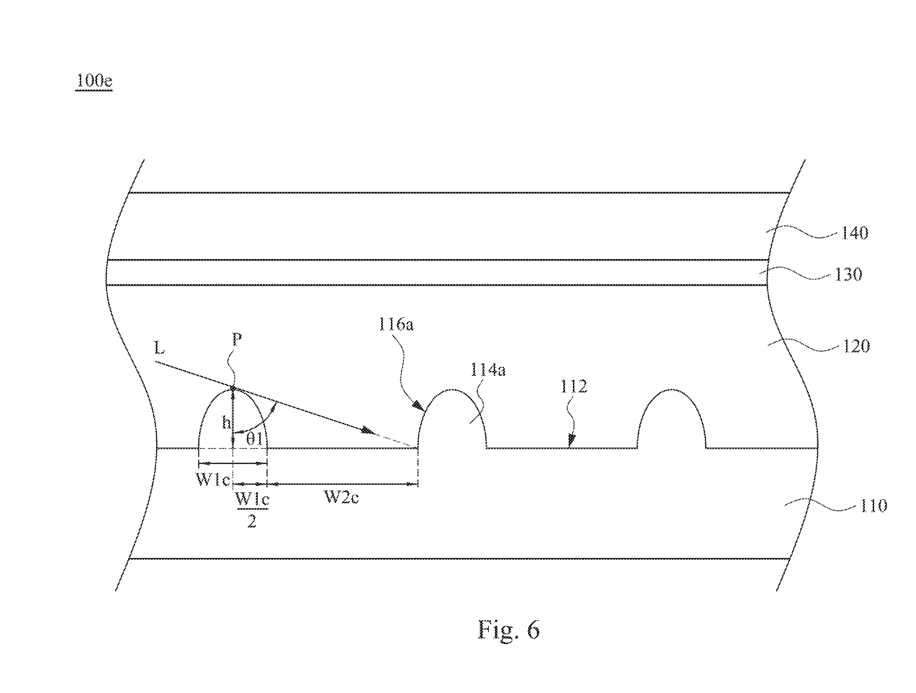

FIG. 6 is a cross-sectional view of a light emitting diode structure 100e according to an embodiment of the present invention. As shown in FIG. 6, the light emitting diode structure 100e includes the patterned substrate 110, the N-type semiconductor layer 120, the light emitting layer 130, and the P-type semiconductor layer 140, and the value of {[(W1c)/2+W2c]/h} is substantially equal to tan 46°. The differences between this embodiment and the embodiment shown in FIG. 2 are that the projection width W1c is smaller than the projection width W1 of FIG. 2, and the interval width W2c is greater than the interval width W2 of FIG. 2.

When the included angle θ1 between the incident light L emitted by the light emitting layer 130 and the perpendicular line passing through the peak P of the protruding portion 114a is greater than 46°, the incident light L can enter the substrate 110 through the light-receiving surface 116a of the protruding portion 114a by the means of the design of the vertical height h, the projection width W1c, and the interval width W2c, such that the incident light L can be refracted or reflected by the protruding portion 114a.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A patterned substrate, comprising a plurality of protruding portions formed on a surface of the substrate, wherein a horizontal projection of each of the protruding portions on the surface has a projection width W1, an interval width W2 is formed between every two adjacent protruding portions, and a vertical height h is formed between a peak of each of the protruding portions and the horizontal surface of the surface of the substrate, wherein the value of {[(W1)/2+W2]/h} is substantially in a range from tan 44° to tan 48°.

2. The patterned substrate of claim 1, wherein each of the protruding portions has a light-receiving surface for refracting or reflecting an incident light.

3. The patterned substrate of claim 2, wherein the light-receiving surface of each of the protruding portions is an oblique surface, and an obtuse angle is formed between the oblique surface and the surface of the substrate.

4. The patterned substrate of claim 2, wherein the light-receiving surface of each of the protruding portions is an arc surface.

5. The patterned substrate of claim 1, wherein cross-sectional shapes of the protruding portions comprise triangle, semicircular, or combinations thereof.

6. The patterned substrate of claim 1, wherein the vertical height h is in a range from 1 μm to 1.5 μm.

7. The patterned substrate of claim 1, wherein [(W1)/2+W2] is in a range from 1.04 μm to 1.56 μm.

8. The patterned substrate of claim 1, wherein a refraction index of the N-type semiconductor layer is substantially equal to 2.5, a refraction index of the substrate is substantially equal to 1.8.

9. The patterned substrate of claim 1, wherein the substrate is a sapphire substrate.

10. A light emitting diode structure comprising:
a patterned substrate, comprising a plurality of protruding portions are formed on a surface of the substrate, wherein a horizontal projection of each of the protruding portions on the surface has a projection width W1, an interval width W2 is formed between every two adjacent protruding portions, and a vertical height h is formed between a peak of each of the protruding portions and the horizontal surface of the surface of the substrate, wherein the value of {[(W1)/2+W2]/h} is substantially in a range from tan 44° to tan 48°;
an N-type semiconductor layer located on the substrate and covering the protruding portions;
a light emitting layer located on the N-type semiconductor layer; and
a P-type semiconductor layer located on the light emitting layer.

11. The light emitting diode structure of claim 10, wherein each of the protruding portions has a light-receiving surface for refracting or reflecting an incident light emitted by the light emitting layer.

12. The light emitting diode structure of claim 11, wherein the light-receiving surface of each of the protruding portions is an oblique surface, and an obtuse angle is formed between the oblique surface and the surface of the substrate.

13. The light emitting diode structure of claim 11, wherein the light-receiving surface of each of the protruding portions is an arc surface.

14. The light emitting diode structure of claim 10, wherein cross-sectional shapes of the protruding portions comprise triangle, semicircular, or combinations thereof.

15. The light emitting diode structure of claim 10, wherein the vertical height h is in a range from 1 μm to 1.5 μm.

16. The light emitting diode structure of claim 10, wherein [(W1)/2+W2] is in a range from 1.04 μm to 1.56 μm.

17. The light emitting diode structure of claim 10, wherein a refraction index of the N-type semiconductor layer is substantially equal to 2.5, and a refraction index of the substrate is substantially equal to 1.8.

18. The light emitting diode structure of claim 10, wherein the substrate is a sapphire substrate.

19. The light emitting diode structure of claim 10, wherein a material of the P-type semiconductor layer is a nitride semiconductor comprising p-type dopant, and a material of the N-type semiconductor layer is a nitride semiconductor comprising N-type dopant.

20. The light emitting diode structure of claim 19, wherein the material of the P-type semiconductor layer is P-type gallium nitride, and the material of the N-type semiconductor layer is N-type gallium nitride.
